(19) United States
(12) Patent Application Publication
(10) Pub. No.: US 2008/0254233 A1
(43) Pub. Date: Oct. 16, 2008

(54) PLASMA-INDUCED CHARGE DAMAGE CONTROL FOR PLASMA ENHANCED CHEMICAL VAPOR DEPOSITION PROCESSES

(76) Inventors: KWANGDUK DOUGLAS LEE, Santa Clara, CA (US); Matthew Spuller, Palo Alto, CA (US); Martin Jay Seamons, San Jose, CA (US); Wendy H. Yeh, Mountain View, CA (US); Bok Hoen Kim, San Jose, CA (US); Mohamad Ayoub, San Jose, CA (US); Amir Al-Bayati, San Jose, CA (US); Derek R. Witty, Fremont, CA (US); Hichem M'Saad, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/733,531

(22) Filed: Apr. 10, 2007

(51) Int. Cl. C23C 14/28

(52) U.S. Cl. 427/595

(57) ABSTRACT

Methods of depositing amorphous carbon films on substrates are provided herein. The methods reduce or prevent plasma-induced charge damage to the substrates from the deposition of the amorphous carbon films. In one aspect, an initiation layer of amorphous carbon is deposited at a low RF power level and/or at a low hydrocarbon compound/inert gas flow rate ratio before a bulk layer of amorphous carbon is deposited. After the deposition of the initiation layer, the RF power, hydrocarbon flow rate, and inert gas flow rate may be ramped to final values for the deposition of the bulk layer, wherein the RF power ramp rate is typically greater than the ramp rates of the hydrocarbon compound and of the inert gas. In another aspect, a method of minimizing plasma-induced charge damage includes depositing a seasoning layer on one or more interior surfaces of a chamber before the deposition of the amorphous carbon film on a substrate therein or coating the interior surfaces with an oxide or dielectric layer during manufacturing.

### BACKGROUND OF THE INVENTION

1. Field of the Invention

Embodiments of the present invention generally relate to the fabrication of integrated circuits. More particularly, embodiments of the present invention relate to methods for depositing an amorphous carbon film on a substrate.

2. Description of the Related Art

In the manufacture of integrated circuits, plasma processes are increasingly being used to replace thermal processes. Plasma processing provides several advantages over thermal processing. For example, plasma enhanced chemical vapor deposition (PECVD) allows deposition processes to be performed at substantially lower temperatures than the temperatures required for analogous thermal processes. This is advantageous for processes with stringent thermal budget demands, such as in very large scale or ultra-large scale integrated circuit (VLSI or ULSI) device fabrication.

However, one problem that has been encountered with plasma processing in integrated circuit fabrication is device damage that occurs as a result of exposure of a device to plasma conditions. It is believed that a non-uniform plasma environment may result in electric field gradients that lead to device damage.

While the susceptibility or degree of device damage typically depends at least partially on the stage of device fabrication and the type of device, many types and stages of devices can experience plasma-induced charge damage. However, in particular, devices containing an insulating or dielectric layer deposited on a substrate are often susceptible to plasma-induced charge damage, as charges accumulate on the surface of the dielectric layer.

For example, plasma-induced charge damage may occur when an amorphous carbon film is deposited in a PECVD process to form a patterning film on a gate oxide layer, such as a thermal oxide layer. As shown in FIG. 1 (Prior Art), in a chamber 100, there is typically a potential difference or electric field (ΔV) between an upper surface 102 and a lower surface 104 of an oxide layer 106 exposed to a plasma 108 during deposition of a layer 120 thereon due to charge buildup on the substrate 101 and chamber electrodes (i.e., face plate 112 and substrate support 114), chamber geometry, and the nature of the plasma. The electric field can cause the trapping of charges within the oxide layer and damage its function as a dielectric layer in a transistor, which may result in failure of the device.

Therefore, there is a need for a method of plasma-enhanced deposition of a film on substrate that reduces or minimizes plasma-induced charge damage to the substrate and device which includes the substrate.

### SUMMARY OF THE INVENTION

Embodiments of the present invention provide methods of depositing an amorphous carbon film on a substrate that prevent or reduce plasma-induced charge damage to the substrate. In one embodiment, a method of depositing an amorphous carbon film comprises introducing a hydrocarbon compound into a chamber and reacting the hydrocarbon compound in the presence of RF power for a period of time to deposit an initiation layer of an amorphous carbon film on the substrate in the chamber. The RF power comprises a first RF power level between about 0.01 W/cm² and about 2 W/cm². A bulk amorphous carbon layer is then deposited on the initiation layer at a second RF power level that is greater than the first RF power level.

In another embodiment, a method of depositing an amorphous carbon film comprises introducing a hydrocarbon compound into a chamber at a first flow rate and introducing an inert gas into the chamber at a second flow rate. The ratio of the first flow rate to the second flow rate is between about 0.001 and about 1000. The inert gas may be any of the gases in the VIII family of the periodic table or a combination thereof. For example, the inert gas may be argon, helium, or a combination thereof.

In another embodiment, a method of depositing an amorphous carbon film includes introducing a hydrocarbon compound and an inert gas into a chamber and reacting the hydrocarbon compound in the presence of RF power for a period of time to deposit an initiation layer of an amorphous carbon film on a substrate in the chamber. After the initiation layer is deposited, the flow rate of the hydrocarbon compound is ramped to a final hydrocarbon compound flow rate, and the flow rate of the inert gas is ramped to a final inert gas flow rate. The RF power is also ramped up to a final RF power level. The RF power may be ramped up to the final RF power level before the flow rate of the inert gas reaches the final inert gas flow rate and before the flow rate of the hydrocarbon compound reaches the final hydrocarbon compound flow rate. A bulk amorphous carbon film is then deposited on the initiation layer.

Further embodiments include depositing a seasoning layer on one or more interior surfaces of a chamber before the bulk deposition of an amorphous carbon film on a substrate in the chamber. In one embodiment, an oxide layer is deposited on a face plate of a chamber or coated on a face plate during the manufacturing of the face plate. In another embodiment, a hydrocarbon compound is introduced into the chamber and is reacted in the presence of RF power to deposit an amorphous carbon film seasoning layer on one or more interior surfaces of the chamber, such as a substrate support of wafer chuck, before a substrate is introduced into the chamber for the deposition of an amorphous carbon layer thereon. A further embodiment includes both depositing an oxide layer on a face plate of a chamber and depositing an amorphous carbon layer on one or more interior surfaces of the chamber, such as a substrate support or wafer chuck.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (Prior Art) is a schematic diagram showing the electric field created across an oxide layer during plasma processing in a chamber.

FIG. 2 is a process flow diagram illustrating a first embodiment of the invention.

FIG. 3 is a process flow diagram illustrating a second embodiment of the invention.

FIG. 4 is a graph showing the RF voltage trace during the deposition of amorphous carbon films using argon or helium-based plasmas.

FIG. 5 is a process flow diagram illustrating a third embodiment of the invention.

FIG. 6 is a graph showing an RF current trace and impedance angle trace as monitored at a face plate electrode during a plasma process.

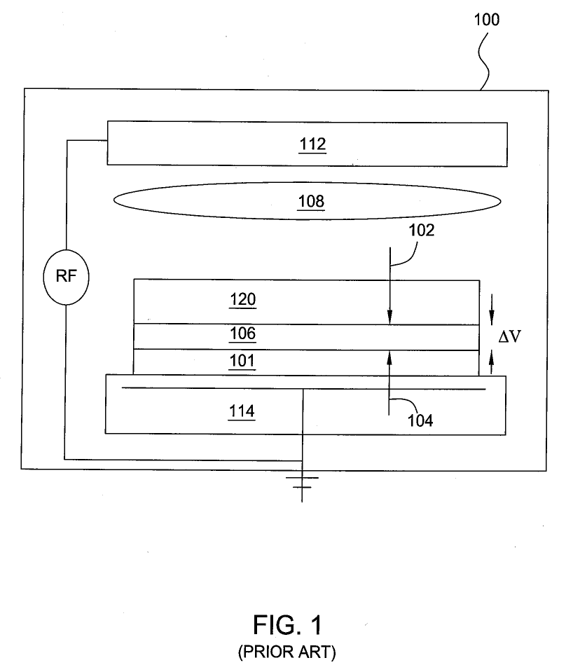

### DETAILED DESCRIPTION

Embodiments of the present invention provide methods of depositing an amorphous carbon film on a substrate that prevent or reduce plasma-induced charge damage to the substrate. Generally, the methods include modifying chamber processing conditions and/or interior surfaces of a chamber before the bulk deposition of an amorphous carbon film on a substrate in the chamber. For example, modifying the chamber processing conditions may comprise depositing an initiation layer of amorphous carbon on a substrate before the deposition of a bulk amorphous carbon film on the substrate, and modifying interior surfaces of the chamber may comprise depositing a seasoning film on one or more interior surfaces of the chamber.

An example of a chamber that may be used to perform embodiments of the invention is a PRODUCER® APF™ chamber, available from Applied Materials, Inc. of Santa Clara, Calif. The PRODUCER® APF™ chamber has two isolated processing regions. The flow rates described throughout the instant application are provided with respect to a 300 mm PRODUCER® APF™ chamber having two isolated processing regions. Thus, the flow rates experienced per each substrate processing region are half of the flow rates into the chamber.

Other chambers that may be used include chambers that are capable of plasma enhanced deposition processes and that include a face plate, i.e., a showerhead of a gas distribution assembly, and a substrate support, both of which may be connected to a source of RF power.

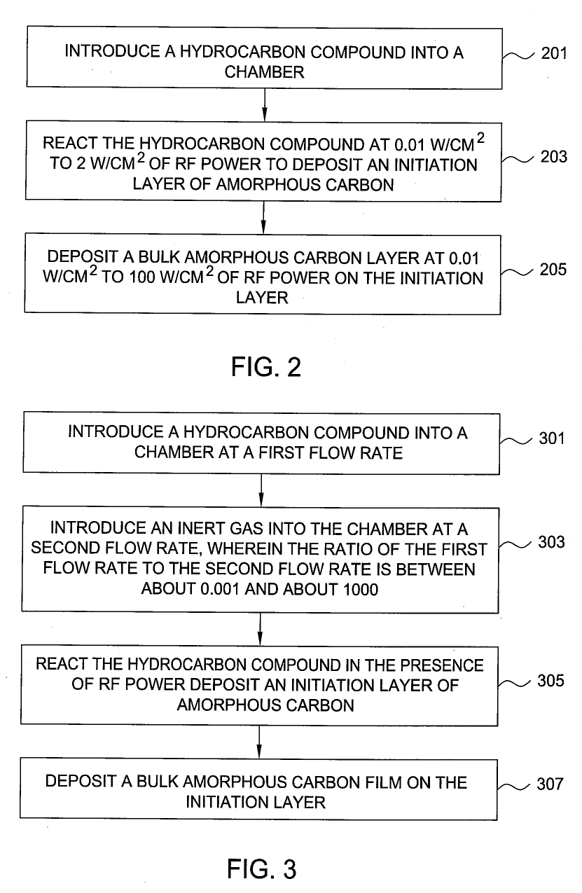

FIG. 2 is a process flow diagram illustrating a first embodiment of the invention. In step 201, a hydrocarbon compound is introduced into a chamber. Typically, an inert gas is also introduced into the chamber. In step 203, the hydrocarbon compound is reacted in the presence of RF power comprising a first RF power level between about 0.01 W/cm² and about 2 W/cm² for a period of time to deposit an initiation layer of an amorphous carbon film on a substrate in the chamber. The RF power may be provided at a single frequency, such as at about 13.56 MHz, or at a mixed frequency, such as at about 13.56 MHz and 350 kHz. The RF power may be maintained at the first RF power level throughout the deposition of the initiation layer or the RF power may be ramped up during the deposition of the initiation layer. For example, the RF power may be ramped up at a rate of between about 0.001 W/cm²/sec and about 1000 W/cm²/sec. The initiation layer may be deposited at a chamber pressure of between about 0.01 Torr and about 100 Torr and a substrate temperature of between about 0° C. and about 1000° C. The initiation layer may have a thickness of between about 0.1 Å and about 5000 Å.

In step 205, a bulk amorphous carbon layer is deposited on the initiation layer at a second RF power level, wherein the second RF power level is greater than the first RF power level. The second RF power level may be between about 0.01 W/cm² and about 100 W/cm². The RF power may be provided at a single frequency, such as at about 13.56 MHz, or at a mixed frequency, such as at about 13.56 MHz and 350 kHz. The bulk amorphous carbon film may be deposited at a substrate temperature of between about 0° C. and about 1000° C., such as between about 300° C. and about 450° C., and at a chamber pressure between about 0.01 Torr and about 100 Torr, such as between about 2 Torr and about 8 Torr.

The bulk amorphous carbon layer may have a thickness of between about 10 Å and about 100,000 Å. The bulk amorphous carbon layer is deposited by continuing the flow into the chamber of the hydrocarbon compound and any inert gases used to deposit the initiation layer.

Methods of depositing amorphous carbon layers are further described in commonly assigned U.S. Pat. No. 6,573,030, U.S. patent application Ser. No. 11/427,324, filed on Jun. 28, 2006, and U.S. patent application Ser. No. 11/451,916, filed on Jun. 13, 2006, which are herein incorporated by reference. Examples of amorphous carbon layers that may be used include APF™ and APF-e films, both of which were developed by Applied Materials, Inc. of Santa Clara, Calif. APF™ and APF-e films may be used with a dielectric anti-reflective coating (DARC) layer thereon, such as a silicon oxynitride layer, to pattern underlying layers of a substrate.

In the embodiment described above with respect to FIG. 2 as well as any of the other embodiments of the invention, the hydrocarbon compound used to deposit the initiation layer and bulk amorphous carbon layer may be any suitable hydrocarbon or hydrocarbon compound, such as hydrocarbon derivatives. Generally, hydrocarbon compounds or derivatives thereof that may be included in the hydrocarbon source may be described by the formula C_{A}H_{B}O_{C}F_{D}, where A has a range of between 1 and 24, B has a range of between 0 and 50, C has a range of 0 to 10, D has a range of 0 to 50, and the sum of B and D is at least 2. Specific examples of suitable hydrocarbon compounds include saturated or unsaturated aliphatic hydrocarbons, saturated or unsaturated alicyclic hydrocarbons, and aromatic hydrocarbons.

Aliphatic hydrocarbons include, for example, alkanes such as methane, ethane, propane, methylpropane, butane, dimethylpropane, pentane, hexane, heptane, octane, nonane, decane, and the like; alkenes such as ethylene, propylene, butylene, pentene, and the like; dienes such as butadiene, isoprene, pentadiene, hexadiene and the like; alkynes such as acetylene, vinylacetylene and the like. Alicyclic hydrocarbons include, for example, cyclopropane, cyclobutane, cyclopentane, cyclopentadiene, and the like. Aromatic hydrocarbons include, for example, benzene, styrene, toluene, xylene, pyridine, ethylbenzene, acetophenone, methyl benzoate, phenyl acetate, phenol, cresol, furan, and the like. Additionally, alpha-terpinene (ATP), cymene, 1,1,3,3,-tetramethylbutylbenzene, t-butylether, t-butylethylene, methyl-methacrylate, and t-butylfurfurylether may be selected.

Examples of suitable derivatives of hydrocarbon compounds are fluorinated alkanes, halogenated alkanes, and halogenated aromatic compounds. Fluorinated alkanes include, for example, monofluoromethane, difluoromethane, trifluoromethane, tetrafluoromethane, monofluoroethane, tetrafluoroethanes, pentafluoroethane, hexafluoroethane, monofluoropropanes, trifluoropropanes, pentafluoropropanes, perfluoropropane, monofluorobutanes, trifluorobutanes, tetrafluorobutanes, octafluorobutanes, difluorobutanes, monofluoropentanes, pentafluoropentanes, tetrafluorohexanes, tetrafluoroheptanes, hexafluoroheptanes, difluorooctanes, pentafluorooctanes, difluorotetrafluorooctanes, monofluorononanes, hexafluorononanes, difluorodecanes, pentafluorodecanes, and the like. Halogenated alkenes include monofluoroethylene, difluoroethylenes, trifluoroethylene, tetrafluoroethylene, monochloroethylene, dichloroethylenes, trichloroethylene, tetrachloroethylene, and the like. Halogenated aromatic compounds include monofluorobenzene, difluorobenzenes, tetrafluorobenzenes, hexafluorobenzene and the like.

In addition to the hydrocarbon compound, one or more inert gases may be used in the deposition of the initiation layer and bulk amorphous carbon layer in any of the embodiments provided herein. The one or more inert gases may be argon, helium, or a combination thereof.

Returning to the embodiment of FIG. 2, it was found that depositing an initiation layer of amorphous carbon film on an oxide layer of a substrate for about 1 second or longer at a low RF power, i.e., between about 0.01 W/cm² and about 2 W/cm², reduced the RF instability in the chamber as measured by the impedance angle. It is believed that the initiation layer functions as a protective layer that takes up a portion of the voltage that is applied across the oxide layer and thus reduces the electric field applied across the oxide layer, resulting in less oxide damage.

It was also found that controlling the rate of RF ramping during the deposition of initiation layer is a factor in controlling plasma-induced charge damage and the resulting device yield. A lower RF ramp rate, i.e., between about 0.001 W/cm²/sec and about 10 W/cm²/sec, is preferred as reduced device yield was observed at high RF ramp rates. Lower RF ramp rates are desirable for minimizing sudden charge build-ups and resulting rushes of current through the layer, e.g., an oxide film, on which the initiation layer is deposited.

FIG. 3 is a process flow diagram illustrating another embodiment of the invention. In step 301, a hydrocarbon compound is introduced into a chamber at a first flow rate. In step 303, an inert gas is introduced into the chamber at a second flow rate. While step 303 is shown as following step 301, steps 301 and 303 may be performed simultaneously. The ratio of the first flow rate to the second flow rate is between about 0.001 and about 1000. In step 305, the hydrocarbon compound is reacted in the presence of RF power for a period of time to deposit an initiation layer of an amorphous carbon film on a substrate in the chamber.

In one embodiment, the inert gas is helium, and the ratio of the first flow rate to the second flow rate is between about 0.001 and about 1000. In another embodiment, the inert gas is argon, and the ratio of the first flow rate to the second flow rate is between about 0.001 and about 1000.

In a further embodiment, the inert gas is an inert gas mixture that includes helium and argon and the hydrocarbon compound is propylene. The ratio of the flow rate of the hydrocarbon compound to the flow rate of the helium is between about 0.001 and about 1000, and the ratio of the flow rate of the hydrocarbon compound to the flow rate of the argon is between about 0.001 and about 1000.

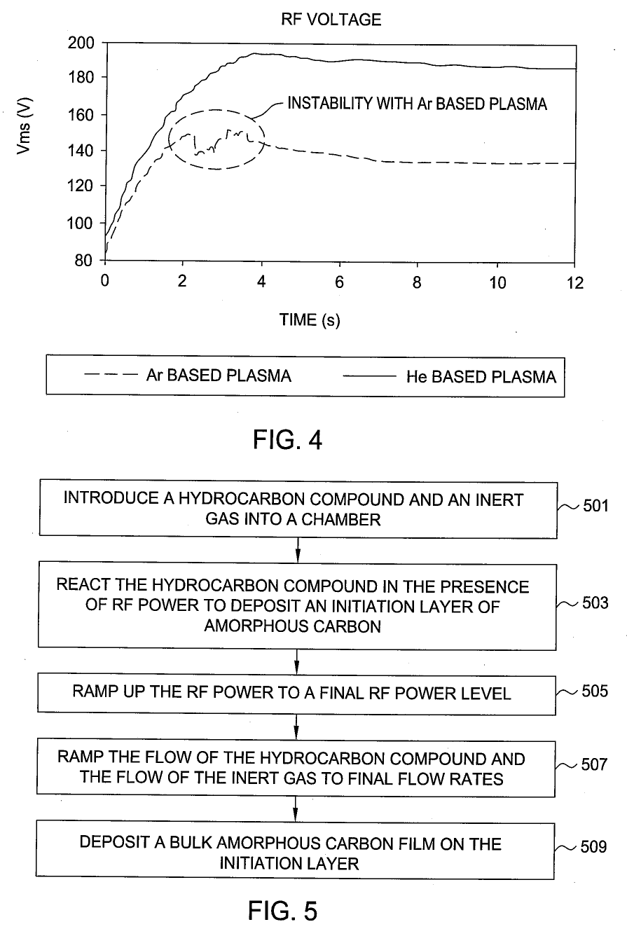

The choice of the inert gas used can reduce plasma-induced charge damage. For example, choosing helium as the inert gas rather than argon can reduce plasma-induced charge damage as helium is more difficult to ionize (24.6 eV ionization potential for He vs. 15.9 eV ionization potential for Ar) and thus provides a lower electron density and lower electrode and surface charging than argon. As shown in FIG. 4, RF voltage traces recorded during the deposition of amorphous carbon films using Ar as the inert gas showed plasma instability while RF voltage traces recorded during the deposition of amorphous carbon films using He did not show plasma instability.

If an inert gas mixture is used, the relative proportion of the inert gases in the mixture can be tailored to reduce plasma-induced charge damage. For example, if a helium and argon mixture is used, using a helium-rich (relative to argon) plasma can reduce plasma-induced charge damage.

As many hydrocarbon compounds have ionization potentials that are lower than argon, using a low hydrocarbon/inert gas flow rate ratio, i.e., between about 0.001 and about 10, can reduce plasma-induced charge damage.

After the deposition of the initiation layer in step 305, the flow rate of the hydrocarbon compound and the flow rate of the inert gas may be adjusted, and the RF power may be ramped up to deposit a bulk amorphous carbon film on the initiation layer, as shown in step 307.

In further embodiments, the relationship between the RF power and gas flow rates during the deposition of a bulk amorphous carbon layer after the deposition of an initiation layer is controlled in order to reduce plasma-induced charge damage. For example, the RF power may be controlled to be ramped up faster than the gas flow rates are adjusted to their final rates for the deposition of the bulk amorphous carbon layer. FIG. 5 is a process flow diagram illustrating such an embodiment. In step 501, a hydrocarbon compound and an inert gas are introduced into a chamber. The hydrocarbon compound may be introduced into the chamber at a flow rate of between about 1 sccm and about 100,000 sccm. In step 503, the hydrocarbon compound is reacted in the presence of RF power, with or without RF ramping, for a period of time to deposit an initiation layer of an amorphous carbon film on a substrate in the chamber. The RF power may be between about 0.01 W/cm² and about 2 W/cm². In step 505, the RF power is ramped up to final RF power level, such as between about 0.01 W/cm² and about 100 W/cm². Then, in step 507, the flow rate of the hydrocarbon compound is ramped to a final flow rate, such as between about 10 sccm and about 100,000 sccm, and the flow rate of the inert gas is ramped to a final flow rate, such as between about 10 sccm and about 100,000 sccm. In step 509, a bulk amorphous carbon film is deposited on the initiation layer.

Although steps 505 and 507 are shown as occurring sequentially, steps 505 and 507 can occur simultaneously. Although typically the RF ramp rate is higher than the gas ramp rates, i.e., the RF power is ramped to its final level before the gases are ramped to their final levels, in other embodiments, the RF ramp rate may not be higher than the gas ramp rates, as long as there is sufficient RF power to dissociate gas in the chamber and maintain a stable plasma.

In addition to controlling the RF power and gas flow rates during a deposition of an initiation layer of amorphous carbon and a subsequent deposition of a bulk amorphous carbon layer, it has been found that other processing conditions can be selected to minimize plasma-induced charge damage. For example, the total flow of gases into the chamber during the deposition of the initiation layer, the chamber pressure during the deposition of the initiation layer, and the spacing between the face plate and the substrate support during the deposition of the initiation layer may be controlled to minimize plasma-induced charge damage. Typically, higher total gas flow rates, e.g., between about 100 sccm and about 100,000 sccm, higher pressures, e.g., between about 1 Torr and about 100 Torr and greater spacings, e.g., between about 100 mils and about 2000 mils, are desirable. A substrate temperature of between about 25° C. and about 750° C. may be used during the deposition of the initiation layer.

Further embodiments of the invention provide methods of reducing plasma-induced charge damage, wherein the methods include modifying, e.g., seasoning, interior surfaces of a chamber before the bulk deposition of an amorphous carbon film on a substrate in the chamber. For example an oxide layer may be deposited on a face plate of a chamber before a hydrocarbon compound is introduced into the chamber and reacted in the presence of RF power to deposit an amorphous carbon film on a substrate in the chamber. The oxide layer may be deposited in situ, i.e., using plasma inside the deposition chamber, or it may be pre-deposited during manufacturing of the faceplate, such as by electrochemical coating. For an in situ deposition, undoped silicon glass (USG) can be deposited from a plasma with SiH₄, N₂O, and inert gases. Other oxidizing plasmas can be used to grow the oxide on the face plate. RF power, such as at a level of between about 0.01 W/cm² and about 100 W/cm², is applied to the face plate during the deposition of the oxide layer. The oxide layer may have a thickness of between about 10 Å and about 10000 Å. RF voltage and impedance angle traces of face plates with 1000 Å-3000 Å of an oxide layer thereon showed almost no RF instability, while RF voltage and impedance angle traces of face plates with about 100 Å of an oxide layer thereon showed RF instability. The thicker oxide layer decreases target capacitance and reduces the charging and voltage drop across the RF plasma sheath, resulting in less charge damage to a layer of a substrate on which an amorphous carbon layer is subsequently deposited.

In another embodiment, an amorphous carbon layer is deposited on one or more interior surfaces of a chamber before the bulk deposition of an amorphous carbon film on a substrate in the chamber. The one or more interior surfaces include a chamber face plate and a substrate support which may also be a wafer chuck or heater. RF power, such as at a level of between about 0.01 W/cm² and about 100 W/cm², is applied to the face plate and/or substrate support during the deposition of the amorphous carbon layer thereon. The amorphous carbon layer may have a thickness between about 10 Å and about 100,000 Å. It was found that depositing the amorphous carbon layer for about 60 seconds corresponded to about a 1500 Å layer and prevented RF instability. The amorphous carbon layer provides a protective seasoning layer on the substrate support that reduces the electric field on a substrate in the chamber and a protective seasoning layer on the face plate that reduces charging on the substrate.

Any of the embodiments of depositing amorphous carbon films provided herein can be used in combination with each other. For example, in a further embodiment, a chamber may be seasoned with an oxide layer or an amorphous carbon layer before depositing an initiation layer of amorphous carbon film on a substrate in the chamber at a first RF power level between about 0.01 W/cm² and about 100 W/cm² and then depositing a bulk amorphous carbon film on the initiation layer at a second RF power level that is greater than the first RF power level. It is also recognized that any of the embodiments provided herein may be used to reduce plasma-induced charge damage to other dielectric films on substrate surfaces besides oxide layers when the dielectric films are subjected to other PECVD processes besides the deposition of amorphous carbon films.

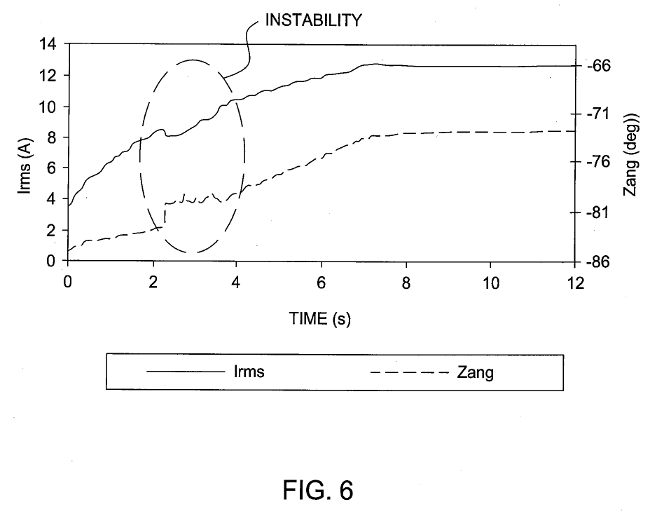

Methods of diagnosing whether certain processing conditions result in plasma-induced charge damage are also provided herein. For example, the RF voltage may be monitored at the face plate electrode to detect plasma instability during plasma processing of a substrate. The RF current and impedance angle may be monitored at the faceplate electrode to detect plasma instability. The RF DC bias voltage measured at the faceplate electrode can also detect plasma instability. In each case, plasma instability is reflected as a region of sudden drops or increases in the factor, i.e., RF voltage, RF current, RF impedance angle, and DC bias, being monitored over a period of plasma processing. For example, FIG. 6 shows a period of plasma instability that is reflected by changes in the RF current and impedance angle during plasma processing.

The monitoring methods described above can be used to evaluate different processing conditions for depositing an amorphous carbon film with no or minimal plasma-induced charge damage to a substrate. Additionally or alternatively, different processing conditions may be evaluated by analyzing the qualities of a thin oxide layer, such as a layer having a thickness of between about 10 Å and about 1000 Å, e.g., about 100 Å, upon which an amorphous carbon layer is deposited under different processing conditions and with different hardware, e.g., seasoned or un-seasoned chamber surfaces, and then removed from the oxide layer, such as by an oxygen or ozone-based ashing process. For example, the relative amount of charges trapped in the thin oxide layer can be measured, e.g., by a Q-V sweep by corona discharge to provide an estimate of the potential plasma-induced damage that may result from a set of processing conditions.

### EXAMPLE

An initiation layer of amorphous carbon was deposited in a 300 mm PRODUCER® APF™ chamber for about 3 seconds to a thickness of about 50 Å on an oxide layer on a substrate. A gas mixture of propylene (C₃H₆), helium, and argon was used for the deposition. The propylene was introduced into the chamber at a flow rate of 200 sccm. The helium was introduced into the chamber at a flow rate of 2000 sccm. The argon was introduced into the chamber at a flow rate of 3600 sccm. The initiation layer was deposited using 13.56 MHz RF power at a level of 1 W/cm² with an RF ramp rate of about 0.3 W/cm²/sec. The substrate temperature was 550° C. and the chamber pressure was 10 Torr. The spacing between the face plate and the substrate support was 250 mils.

The RF power was then ramped up to 2.2 W/cm² at a ramp rate of 0.3 W/cm²/sec. The propylene flow rate was changed to 1600 sccm with 300 sccm/sec ramp rate, the helium flow rate was changed to 400 sccm, and the argon flow rate was changed to 3600 sccm. The final gas flow rates were achieved after the RF power reached 2.2 W/cm². A bulk amorphous carbon layer was then deposited on the initiation layer.

While the foregoing is directed to embodiments of the present invention, other and further embodiments of the invention may be devised without departing from the basic scope thereof, and the scope thereof is determined by the claims that follow.

What is claimed is:

1. A method of depositing an amorphous carbon film, comprising:
introducing a hydrocarbon compound into a chamber;
reacting the hydrocarbon compound in the presence of RF power comprising a first RF power level between about 0.01 W/cm² and about 2 W/cm² for a period of time to deposit an initiation layer of an amorphous carbon film on a substrate in the chamber;
depositing a bulk amorphous carbon film on the initiation layer at a second RF power level, wherein the second RF power level is greater than the first RF power level.

2. The method of claim 1, wherein the thickness of the initiation layer is between about 10 Å and about 1000 Å.

3. The method of claim 1, wherein the RF power is maintained at the first RF power level throughout the deposition of the initiation layer.

4. The method of claim 1, wherein the RF power is ramped up during the deposition of the initiation layer.

5. The method of claim 4, wherein the RF power is ramped up at a rate of between about 0.001 W/cm²/sec and about 1000 W/cm²/sec.

6. The method of claim 1, further comprising seasoning the chamber before the deposition of the initiation layer, wherein seasoning the chamber comprises depositing an amorphous carbon layer on one or more interior surfaces of the chamber.

7. A method of depositing an amorphous carbon film, comprising:
introducing a hydrocarbon compound into a chamber at a first flow rate;
introducing an inert gas into the chamber at a second flow rate, wherein a ratio of the first flow rate to the second flow rate is between about 0.001 and about 1000;
reacting the hydrocarbon compound in the presence of RF power for a period of time to deposit an initiation layer of an amorphous carbon film on a substrate in the chamber.

8. The method of claim 7, wherein the inert gas is helium, and the ratio of the first flow rate to the second flow rate is between about 0.001 and about 1000.

9. The method of claim 7, wherein the inert gas is argon, and the ratio of the first flow rate to the second flow rate is between about 0.001 and about 1000.

10. The method of claim 7, wherein the inert gas comprises helium and argon, and the ratio of the flow rate of the hydrocarbon compound to the flow rate of the helium is between about 0.001 and about 1000, and the ratio of the flow rate of the hydrocarbon compound to the flow rate of the argon is between about 0.001 and about 1000.

11. The method of claim 7, wherein the total flow rate of the hydrocarbon compound and inert gases into the chamber is between about 0.01 sccm/cm² and about 1000 sccm/cm².

12. The method of claim 7, wherein the RF power comprises an RF power level between about 0.01 W/cm² and about 100 W/cm².

13. The method of claim 7, further comprising ramping up the RF power after the deposition of the initiation layer and depositing a bulk amorphous carbon film on the initiation layer.

14. The method of claim 7, further comprising adjusting the flow rate of the hydrocarbon compound and the flow rate of the inert gas after the deposition of the initiation layer and depositing a bulk amorphous carbon film on the initiation layer.

15. A method of depositing an amorphous carbon film, comprising:
introducing a hydrocarbon compound and an inert gas into a chamber;
reacting the hydrocarbon compound in the presence of RF power for a period of time to deposit an initiation layer of an amorphous carbon film on a substrate in the chamber;
after the deposition of the initiation layer, ramping a flow rate of the hydrocarbon compound to a final hydrocarbon compound flow rate, ramping a flow rate of the inert gas to a final inert gas flow rate, and ramping up the RF power to a final RF power level; and then
depositing a bulk amorphous carbon film on the initiation layer.

16. The method of claim 15, wherein the RF power during the deposition of the initiation layer comprises an RF power level between about 0.01 W/cm² and about 2 W/cm².

17. The method of claim 15, wherein the RF power is ramped up to the final RF power level before the flow rate of the inert gas reaches the final inert gas flow rate and before the flow rate of the hydrocarbon compound reaches the final hydrocarbon compound flow rate.

18. A method of depositing an amorphous carbon film, comprising:
depositing an oxide layer on a face plate of a chamber;
introducing a hydrocarbon compound into the chamber after the deposition of the oxide layer;
reacting the hydrocarbon compound in the presence of RF power to deposit an amorphous carbon film on a substrate in the chamber.

19. The method of claim 18, wherein RF power is applied to the face plate during the deposition of the oxide layer.

20. The method of claim 19, wherein the oxide layer has a thickness of between about 10 Å and about 10,000 Å.
